(19) United States
(12) Patent Application Publication
(10) Pub. No.: US 2011/0255261 A1
(43) Pub. Date: Oct. 20, 2011

(54) Frame For Retaining A Display Screen

(76) Inventors: Mark S Tracy, Tomball, TX (US); Earl W. Moore, Cypress, TX (US); Paul N. Walker, Cypress, TX (US)

(21) Appl. No.: 13/140,835

(22) PCT Filed: Dec. 22, 2008
(86) PCT No.: PCT/US08/88076

§ 371 Date: Jun. 18, 2011

(51) Int. Cl. H05K 7/02; H05K 5/02

(52) U.S. Cl. 361/807; 312/223.1

(57) ABSTRACT

Frame for retaining a display screen. At least some illustrative embodiments are enclosures comprising a frame member that defines a substantially flat inner surface and a substantially flat outer surface, and the frame member comprises a portion of a perimeter of the frame member that is bent to create a flange that is substantially perpendicular to the inner surface of the frame member, an outer covering member thermally bonded to the outer surface of the frame member, and a plurality of retaining members configured to retain a display screen proximate to the inner surface of the frame member.

### BACKGROUND

A display screen mounted within a mobile computing system experiences compressive forces (e.g., when the mobile computing system is dropped) which may cause damage to the display screen or to an assembly that mounts the display screen within the mobile computing system. With the marketing trends moving towards mobile computing systems with decreased design thickness and weight, it is difficult to select an external covering of the mobile computing system that provides a good balance of protection against compressive forces, weight and cost.

### BRIEF DESCRIPTION OF THE DRAWINGS

For a detailed description of exemplary embodiments, reference will now be made to the accompanying drawings in which:

FIG. 1 shows a mobile computing system in accordance with some embodiments;

FIG. 2 shows a frame member in accordance with some embodiments;

FIG. 3A shows a press-fit system in accordance with some embodiments;

FIG. 3B shows a retaining member in accordance with some embodiments;

FIG. 4 shows an end-view of a frame member in accordance with some embodiments; and

FIG. 5 shows a frame member and an outer covering member in accordance with some embodiments.

### NOTATION AND NOMENCLATURE

Certain terms are used throughout the following description and claims to refer to particular system components. As one skilled in the art will appreciate, computer companies may refer to a component by different names. This document does not intend to distinguish between components that differ in name but not function.

In the following discussion and in the claims, the terms “including” and “comprising” are used in an open-ended fashion, and thus should be interpreted to mean “including, but not limited to . . . .” Also, the term “couple” or “couples” is intended to mean either an indirect or direct connection. Thus, if a first device couples to a second device, that connection may be through a direct connection or through an indirect connection via other devices and connections.

### DETAILED DESCRIPTION

The following discussion is directed to various embodiments. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

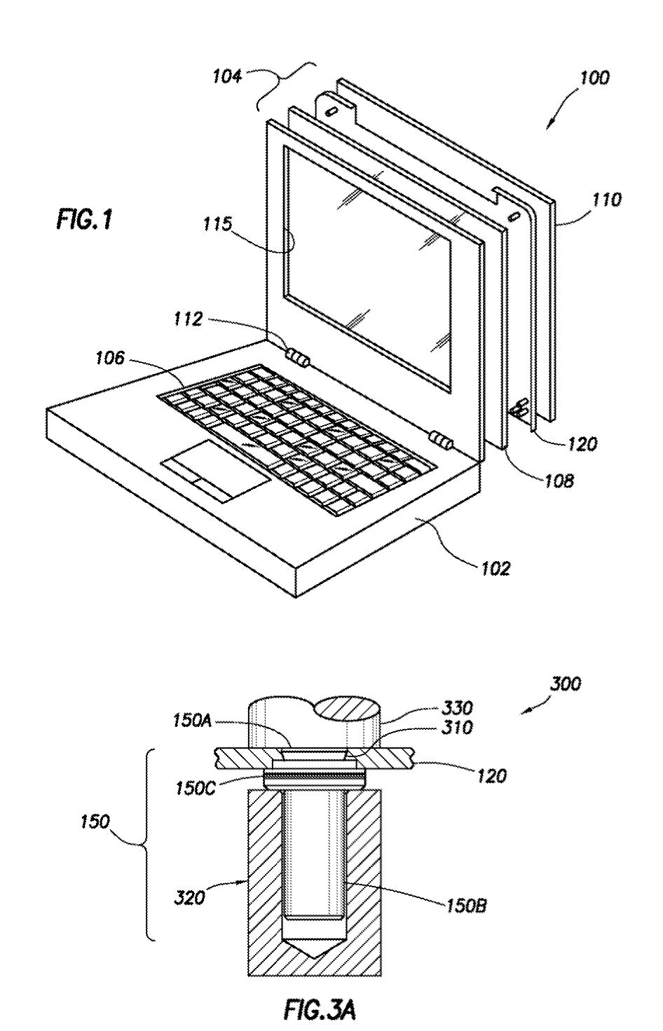

FIG. 1 illustrates a mobile computing system 100 in accordance with at least some embodiments. The mobile computing system comprises a first chassis 102 and a second chassis 104, and the first chassis 102 couples to the second chassis by way of a hinge 112. The first chassis 102 comprises a user interface, such as a keyboard 106. So that the information may be conveyed to a user, the second chassis 104 of the mobile computing system 100 comprises a display screen 108 visible through an aperture 115 in the second chassis 104. In some embodiments, the second chassis 104 may also be referred to as an enclosure comprising a display screen 108.

The second chassis 104 of the mobile computing system 100 comprises a display screen 108 and an outer covering member 110. For example, the display screen 108 may be a Liquid Crystal Display (LCD) screen, and the outer covering member 110 may be formed from injection molded plastic or a die cast metal. In related art devices, the display screen 108 is directly mounted to the outer covering member 110 by installing fasteners (e.g., screws) through apertures of the display screen 108. By mounting the display screen 108 directly to the outer covering member 110, the compression forces experienced by the outer covering member 110, for example on the outer surface, are transferred to the display screen 108 possibly causing damage to the display screen 108. Additionally, in the instances that the mobile computing system 100 is dropped, the impact flexes the second chassis 104 causing failures at the fasteners mounting the display screen 108 to the outer covering member 110. In accordance with the various embodiments, a frame member 120 is utilized to reduce the risk of damage to the display screen 108 mounted within the second chassis 104 by any such compressive forces.

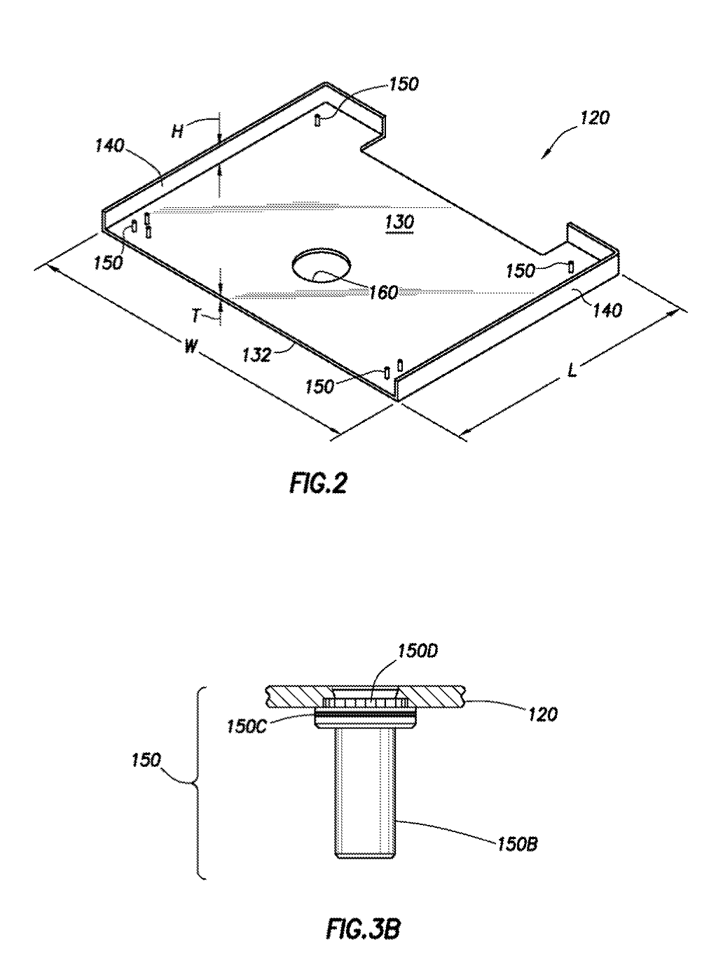

FIG. 2 illustrates the frame member 120 in accordance with at least some embodiments. In particular, the frame member 120 comprises a substantially flat inner surface 130 and a substantially flat outer surface 132. In some embodiments, the outer covering member 110 (FIG. 1) is coupled to the outer surface 132, and the display screen 108 is mounted proximate to the inner surface 130 of the frame member 102. In order to reduce the risk of damage to the display screen 108 and to increase the overall stiffness of the second chassis 104, in accordance with at least some embodiments the frame member 120 is constructed of an aluminum alloy, such as 6061-T6 aluminum alloys or 6063 aluminum alloys. Such alloys of aluminum may be equivalently referred to as “6000 grade” aluminum and/or “aircraft grade” aluminum. In other embodiments, the frame member 120 may be constructed of other metals, such as magnesium or alloys such as steel.

In at least some embodiments, the frame member 120 is formed by a forming mechanism that utilizes a tooling plate (e.g., an aluminum tooling plate). In other embodiments, other forming mechanism may be equivalently used, for example, an injection molding process, a die casting process, or a stamping process.

In some embodiments, the length ‘L’ and the width ‘W’ of the frame member 120 is selected based on the dimensions of the display screen 108 mounted proximate to the inner surface 130. For example, the display screen 108 may be a 15 inch Liquid Crystal Display screen, and thus the length ‘L’ and the width ‘W’ may be selected to accommodate the 15 inch display screen. Thickness ‘T’ of the frame member is selected to provide a good balance of protection against compressive forces, stiffness, cost and weight. In at least some embodiments, the thickness ‘T’ of the frame member 120 may be 0.5 millimeters (mm) or greater.

In at least some embodiments, in order to reduce the weight of the frame member 120, the frame member 120 comprises an aperture 160 through the frame member 120. The aperture 160 may be located at any suitable location within the boundary of the frame member 120. In other embodiments, the frame member 120 may comprise a plurality of apertures 160 to further reduce the weight of the frame member 120. Likewise, the aperture 160 is shown as a circle, but any form such as a square, a rectangle, or an oval may be equivalently used, and the aperture 160 may be of any size that prevents damage from the compressive forces.

In some embodiments, in order to increase the overall stiffness of the frame member 120, the frame member 120 may be bent along a portion of a perimeter of the frame member 120 to create flange 140. In particular, the frame member 120 is bent to create the flange 140 that is in a direction substantially perpendicular to the inner surface 130. In some embodiments, the height of the flange 140 may be 0.8 millimeters (mm) or greater. In the embodiments of FIG. 2 the flange 140 spans the length ‘L’ of the frame member 120; however, in other embodiments, the flange 140 may span only selected portions of the length ‘L’ or the width ‘W’ of the frame member 120. In yet still other embodiments, the flange 140 may be omitted.

In at least some embodiments, the frame member 120 comprises a plurality of retaining members 150 configured to retain the display screen proximate to the inner surface 130 of the frame member 120. The retaining members 150 are fasteners, such as self-clinching nuts that clinch to a corresponding mounting aperture in the frame member 120. The retaining members 150 in accordance with the various embodiments are resistant to “spin-out”, “pull-out” or “torque-out” of the corresponding mounting aperture. Because the retaining members 150 are resistant to “spin-out”, “pull-out” or “torque-out”, the retaining members 150 provide protection against flexing of the second chassis 104. In other embodiments, the frame member 120 may comprise any number of retaining members 150, and the retaining members 150 may be located at any suitable location within the frame member 120. The self-clinching nuts in accordance with the various embodiments are available from PennEngineering of Danboro, Pa.

In accordance with at least some embodiments, the retaining members 150 are press-fit with a corresponding mounting aperture in the frame member 120. FIG. 3A illustrates, in a cross section, such a system 300 for press-fitting the retaining member 150. The system 300 comprises an anvil 320 and a punch 330. Mounting aperture 310 is created (e.g., by drilling or by milling) in the frame member 120, and the shank end 150A of the retaining member 150 is held within the mounting aperture 310. In some cases, the inside diameter of the mounting aperture 310 is selected based on the outside diameter of the shank end 150A. The anvil 320 holds the barrel 150B of the retaining member 150, and once the shank enc 150A and the barrel 150B are properly held, a squeezing force is applied by way of the punch 330 until the flange 150C is in contact with the frame member 120.

FIG. 3B illustrates the retaining member 150 press-fit with the corresponding mounting aperture in the frame member 120. In particular, FIG. 3B illustrates the flange 150C in contact with the frame member 120. Serrated clinching ring 150D reduces the “spin-out”, “pull-out” or “torque-out” of the retaining member 150 from the corresponding mounting aperture 310.

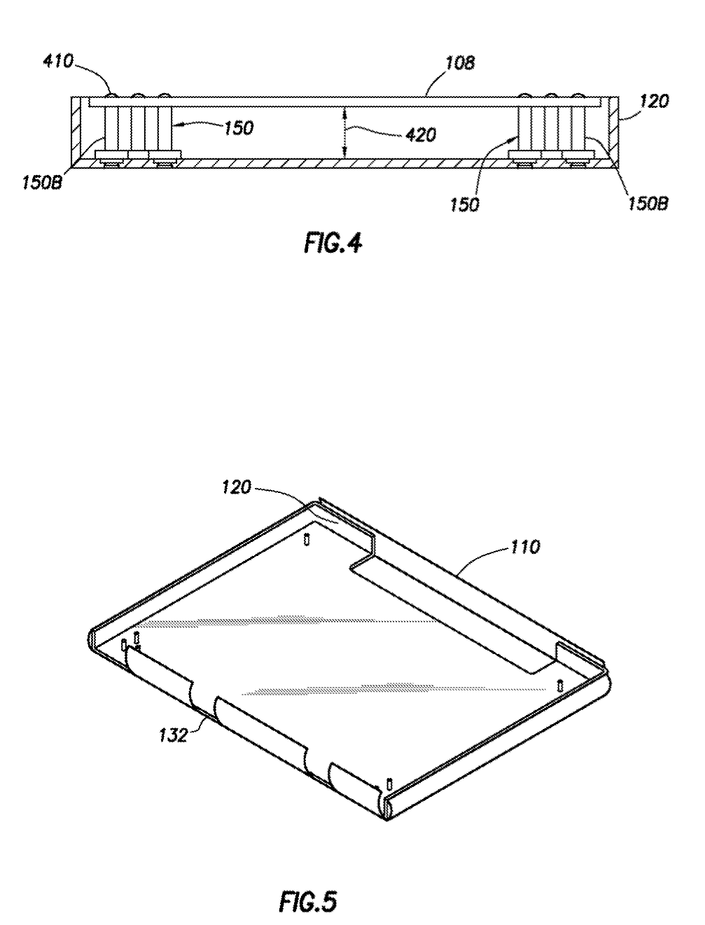

FIG. 4 illustrates an end-view of the frame member 120 with a display screen 108 (e.g., Liquid Crystal Display screen) retained proximate to the inner surface 130. In particular, the display screen 108 is mechanically mounted to the frame member 120 by way of the retaining members 150. For example, if retaining members 150 are as illustrated in the embodiment of FIG. 3, then the display screen 108 is mounted proximate (e.g., within 15 millimeters) to the frame member 120 by installing fasteners 410 through particular apertures of the display screen 108. In the particular case, the fasteners 410 installed through the apertures of the display screen 108 are retained in the barrel 150B of the retaining members 150. In the embodiment of the FIG. 4 the retaining members 150 are selected to allow a clearance space 420 below the display screen 108. In the exemplary embodiment, the clearance space 420 may enable airflow across the display screen 108 for heat transfer purposes, and may provide room for displacement of the frame member 120 caused by compression forces applied to the mobile computing system 100. In other embodiments, the display screen 108 may contact the inner surface 130 of the frame member 120.

FIG. 5 illustrates the frame member 120 coupled to the outer covering member 110. The outer covering member 110 is coupled to the outer surface 132 of the frame member 120, and the outer covering member 110 forms the exterior surface of the second chassis 104 of the mobile computing system 100. In some embodiments, the outer covering member 110 is thermally bonded to the frame member 120. In other embodiments, the outer covering member 110 and the frame member 120 are coupled by depositing an adhesive between the outer covering member 110 and the frame member 120. Because the frame member 120 of the various embodiments is designed and constructed to reduce the risk of damage to the display screen 108 by compressive forces, the outer covering member 110 may be selected to provide a good balance of cost and weight. In some cases, the outer covering member 110 may be constructed from any material, such as plastic, carbon fiber or metal, and the outer covering member 110 may be fabricated by any process, such as injection molding, die casting, or thermally forming. In other embodiments, the outer covering member 110 may be selected to produce aesthetically pleasing mobile computing system 100.

The above discussion is meant to be illustrative of the principles and various embodiments of the present invention. Numerous variations and modifications will become apparent to those skilled in the art once the above disclosure is fully appreciated. For example, the mobile computing system may be any mobile computing system such as a mobile telephone, a personal digital assistant (PDA), a camera or any other mobile computing system. Moreover, the mobile computing system 100 may comprise only a first chassis including a user interface, such as a touch screen, a pointer device, a keyboard. It is intended that the following claims be interpreted to embrace all such variations and modifications.

What is claimed is:

1. An enclosure comprising:
a frame member that defines a substantially flat inner surface and a substantially flat outer surface, and the frame member comprises a portion of a perimeter of the frame member that is bent to create a flange that is substantially perpendicular to the inner surface of the frame member;
an outer covering member thermally bonded to the outer surface of the frame member; and
a plurality of retaining members configured to retain a display screen proximate to the inner surface of the frame member.

2. The enclosure as defined in claim 1 wherein the plurality of retaining members extend from the frame member opposite the outer covering member, and each of the plurality of retaining members in a press-fit with a corresponding mounting aperture of the frame member.

3. The enclosure as defined in claim 2 wherein each of the plurality of retaining members is a fastener configured to clinch to the corresponding mounting aperture of the frame member.

4. The enclosure as defined in claim 1 wherein the frame member further comprises an aperture configured to reduce weight of the frame member.

5. The enclosure as defined in claim 1 wherein the frame member is at least one selected from the group consisting or: aluminum; steel; and magnesium.

6. The enclosure as defined in claim 1 wherein the outer covering member is plastic.

7. The enclosure as defined in claim 1 wherein the display screen is a liquid crystal display screen.

8. A system comprising:
a first chassis that comprises a keyboard;
a second chassis hinged to the first chassis, the second chassis comprising:
a display screen;
a frame member, that defines an inner surface and an outer surface;
an outer covering member thermally bonded to the outer surface of the frame member; and
a plurality of retaining members that extend from the frame member opposite the outer covering member, each of the plurality of retaining members in press-fit with a corresponding mounting aperture of the frame member, and the plurality of retaining members configured to retain a display screen proximate to the inner surface of the frame member.

9. The system as defined in claim 8 wherein a portion of a perimeter of the frame member is bent to create a flange that is substantially perpendicular to the inner surface of the frame member.

10. The system as defined in claim 8 wherein the frame member is at least one selected from the group consisting or: aluminum; steel; and magnesium.

11. The system as defined in claim 8 wherein each of the plurality of retaining members is a fastener configured to clinch to the corresponding mounting aperture of the frame member.

12. The system as defined in claim 8 wherein the frame member further comprises an aperture configured to reduce weight of the frame member.

13. An enclosure for a display screen comprising:
a frame member that defines an inner surface and an outer surface, the frame member comprises a portion of a perimeter of the frame member that is bent to create a flange that is substantially perpendicular to the inner surface of the frame member, and the frame member further comprises an aperture configured to reduce weight the frame member:
an outer covering member thermally bonded to the outer surface of the frame member; and
a plurality of retaining members configured to retain the display screen proximate to the inner surface of the frame member.

14. The enclosure as defined in claim 13 wherein the plurality of retaining members extend from the frame member opposite the outer covering member, and each of the plurality of retaining members in a press-fit with a corresponding mounting aperture of the frame member.

15. The enclosure as defined in claim 14 wherein each of the plurality of retaining members is a fastener configured to clinch to the corresponding mounting aperture of the frame member.
